(19) United States
(12) Patent Application Publication
(10) Pub. No.: US 2021/0149782 A1
(43) Pub. Date: May 20, 2021

(54) TEST METHOD, SYSTEM, READABLE STORAGE MEDIUM AND ELECTRONIC DEVICE FOR PROCESS CONTROL

(71) Applicants: Inventec (Pudong) Technology Corporation, Shanghai (CN); INVENTEC CORPORATION, Taipei (TW)

(72) Inventor: Baodong SONG, Tianjin (CN)

(73) Assignees: Inventec (Pudong) Technology Corporation, Shanghai (CN); INVENTEC CORPORATION, Taipei (TW)

(21) Appl. No.: 17/095,759

(22) Filed: Nov. 12, 2020

(30) Foreign Application Priority Data
Nov. 20, 2019 (CN) 201911142352X

(51) Int. Cl. G06F 11/26; G01R 31/317; G06F 13/42

(52) U.S. Cl. CPC G06F 11/26; G01R 31/31724; G06F 2213/0006; G06F 13/4221; G06F 2213/0024; G01R 31/31707

(57) ABSTRACT

The present disclosure provides a test method, system, readable storage medium and electronic device for process control. The test method for process control is adapted to an electronic device configured with a first test platform for serial testing and a second test platform for parallel testing. The test method for process control includes: determining whether to switch to the second test platform according to the test parameters in the preset test tool after entering the testing process; if yes, switching to the second test platform to call the second test platform to perform parallel testing with the first test platform; collecting the flag file that includes the test result after the test is over; if not, calling only the first test platform to perform serial testing. The testing process coordinates with the test tool, which greatly saves the pressure test time of the test tool and improves the productivity.

### CROSS REFERENCE TO RELATED APPLICATION

This application claims the benefits of priority to Chinese Patent Application No. CN 201911142352X, entitled “Test Method, System, Readable Storage Medium and Electronic Device for Process Control”, filed with CNIPA on Nov. 20, 2019, the contents of which are incorporated herein by reference in its entirety.

### BACKGROUND

### Field of Disclosure

The present disclosure belongs to the field of server testing technology, and relates to a test method and system, in particular, to a test method, system, readable storage medium and electronic device for process control.

### Description of Related Arts

In the server testing process of the current production line, the testing process is always performed step by step according to the test tool. The overall testing process and time are stable, but would take a long time. Although some test tools can perform parallel testing themselves, they are more limited in operation and would be restricted by the tools themselves, which is inconvenient and inflexible. The early detection of production line test problems and efficiency improvement are still facing much stress.

Therefore, how to provide a test method, system, readable storage medium and electronic device for process control, to solve the problem in traditional technologies, has become an urgent technical problem for the skilled in the art.

### SUMMARY

The present disclosure provides a test method, system, readable storage medium and electronic device for process control, to solve the problem of traditional technologies that the server testing process is performed step by step according to the test tools, which would be restricted by the test tools, leading to defects such as longer test time and inflexibility.

In an aspect, the present disclosure provides a test method for process control, which is adapted to an electronic device configured with a first test platform for serial testing and a second test platform for parallel testing. The test method for process control includes: determining whether to switch to the second test platform according to the test parameters in the preset test tool after entering the testing process; if yes, switching to the second test platform to call the second test platform to perform parallel testing with the first test platform; collecting the flag file that includes the test result after the test is over; if not, calling only the first test platform to perform serial testing.

In an embodiment of the present disclosure, the preset test tool includes a test script to test a function of the object to be tested; the test script includes the test parameters.

In an embodiment of the present disclosure, when serial testing is required, the test parameters only include functional test parameters of the object to be tested; when parallel testing is required, the test parameters further include a parameter marker indicating a need to switch to the second test platform for parallel testing.

In an embodiment of the present disclosure, if it is necessary to switch to the second test platform, the test method for process control further includes copying the preset test tool to an independent running directory for operation.

In an embodiment of the present disclosure, the preset test tools are freely combined on the second test platform to realize parallel testing on the second test platform.

In an embodiment of the disclosure, the test result includes passing a parallel testing or failing a parallel testing.

In another aspect, the present disclosure provides a test system for process control, which is adapted to an electronic device configured with a first test platform for serial testing and a second test platform for parallel testing. The test system for process control includes: a determining module to determine whether to switch to the second test platform according to the test parameters in the preset test tool after entering the testing process; if yes, switching to the second test platform by a calling module to call the second test platform to perform parallel testing with the first test platform; collecting the flag file that includes the test result by a collecting module after the test is over; if not, calling the first test platform by the calling module to perform serial testing.

In an embodiment of the present disclosure, the test system for process control further includes: a memory module to store the preset test tool.

In yet another aspect, the present disclosure provides a readable storage medium having stored thereon a computer program. When executed by a processor, the program implements the test method for process control.

In a final aspect, the present disclosure provides an electronic device, including: a processor and a memory; the memory is configured to store a computer program, and the processor is configured to execute the computer program stored in the memory, so that the electronic device implements the test method for process control.

As described above, the test method, system, readable storage medium and electronic device for process control as described in the present disclosure has the following beneficial effects:

First, the overall test is more flexible and convenient. There is no limitation from the test tools, therefore, the test tools may be flexibly combined.

Second, the grabs of running directories and flag files are relatively independent and would not interfere with each other.

Third, through the conditions of the background parameter marker in the test tool, the testing process coordinates with the test tool to flexibly control the parallelism of the test tool, which greatly saves the pressure measurement test time of the test tool and improves the productivity. The problems of the device to be tested could be discovered early, so that corrections could be made timely to facilitate subsequent testing and shipment.

### BRIEF DESCRIPTION OF THE DRAWINGS

FIG. 1 is a schematic diagram of the electronic device applicable to a test method for process control of the present disclosure.

FIG. 2A is a schematic flowchart of a test method for process control in an embodiment of the present disclosure.

FIG. 2B is a specific embodiment diagram of the test method for process control of the present disclosure.

FIG. 3 is a schematic diagram of a test system for process control in an embodiment of the present disclosure.

FIG. 4 shows a schematic diagram of the hardware of the electronic device of the present disclosure.

### DESCRIPTION OF REFERENCE NUMERALS

1 Server
3 Test system for process control
31 Memory module
32 Starting module
33 Determining module
34 Calling module
35 Collecting module
36 Cycling module
4 Electronic device
41 Processor
42 Memory
43 Transceiver
44 Communication interface
45 System bus
S21˜S26 steps

### DETAILED DESCRIPTION OF THE PREFERRED EMBODIMENTS

The embodiments of the present disclosure will be described below through exemplary embodiments. Those skilled in the art can easily understand other advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure. It needs to be stated that the following embodiments and the features in the embodiments can be combined with one another under the situation of no conflict.

It needs to be stated that the drawings provided in the following embodiments are just used for schematically describing the basic concept of the present disclosure, thus only illustrating components only related to the present disclosure and are not drawn according to the numbers, shapes and sizes of components during actual implementation, the configuration, number and scale of each component during the actual implementation thereof may be freely changed, and the component layout configuration thereof may be more complex.

### Embodiment 1

This embodiment provides a test method for process control, which is adapted to an electronic device configured with a first test platform for serial testing and a second test platform for parallel testing. The test method for process control includes:

determining whether to switch to the second test platform according to the test parameters in the preset test tool after entering the testing process; if yes, switching to the second test platform to call the second test platform to perform parallel testing with the first test platform; collecting the flag file that includes the test result after the test is over; if not, calling only the first test platform to perform serial testing.

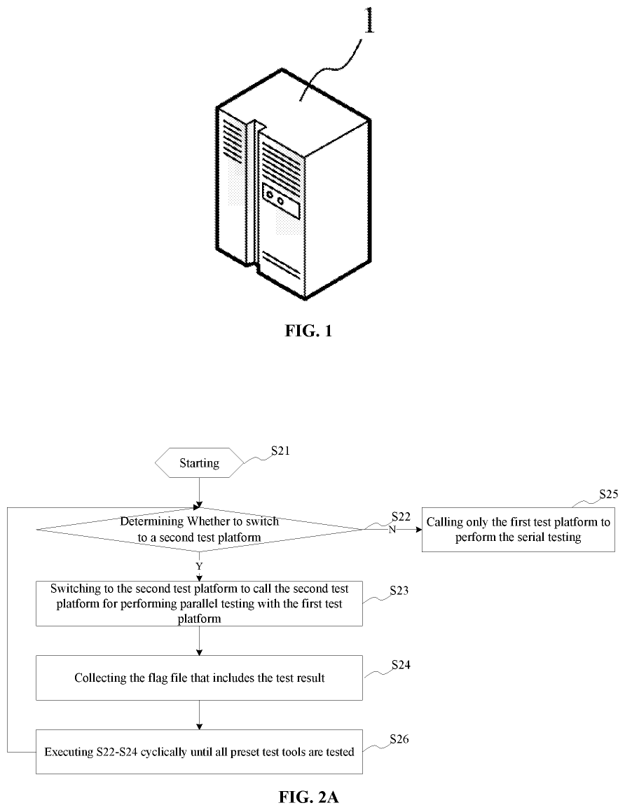

The test method for process control provided in this embodiment will be described in detail below with reference to the drawings. The test method for process control described in this embodiment is used to test an electronic device, for example, server 1 as shown in FIG. 1, to discover problems existing in an electronic device in advance, and facilitate timely correction, subsequent testing and shipment.

In this embodiment, the electronic device is configured with a first test platform (hereafter referred to as foreground) for serial testing and a second test platform (hereafter referred to as background) for parallel testing.

Before executing the test method for process control described in this embodiment, a test tool needs to be preset. Therefore, the preset test tool includes a test script to test a function of the object to test script, the test script may be automatically called by the testing process; the test script includes the test parameters. In this embodiment, when serial testing is required, the test parameters only include functional test parameters of the object to be tested; when parallel testing is required, the test parameters further include a parameter marker to indicate a need to switch to the second test platform for parallel testing. Specifically, the parameter marker that needs to be switched to the background for parallel testing is “background”.

Examples of test scripts included in the test tool are as follows:

VGA_TEST.SH

NIC_TEST.SH

NIC_END.SH

HDD_TEST.SH

CPU_TEST.SH

CPU_END.SH.

Specific examples of test parameters are as follows:

INDEX=1 NAME=VGA_TEST PARAMS=LED_Green

INDEX=2 NAME=NIC_TEST PARAMS=background nicstress (second test platform in parallel)

INDEX=3 NAME=NIC_END PARAMS=NA

INDEX=4 NAME=HDD_TEST PARAMS=hdd.json

INDEX=5 NAME=CPU_TEST PARAMS=background cpu.json (second test platform parallel)

INDEX=6 NAME=CPU_END PARAMS=NA.

In this embodiment, the preset test tools are freely combined on the second test platform to realize parallel testing on the second test platform.

For example, INDEX=2 NAME=NIC_TEST PARAMS=background nicstress; (second test platform in parallel);

INDEX=2 NAME=CPU_TEST PARAMS=background cpu.json (second test platform in parallel)

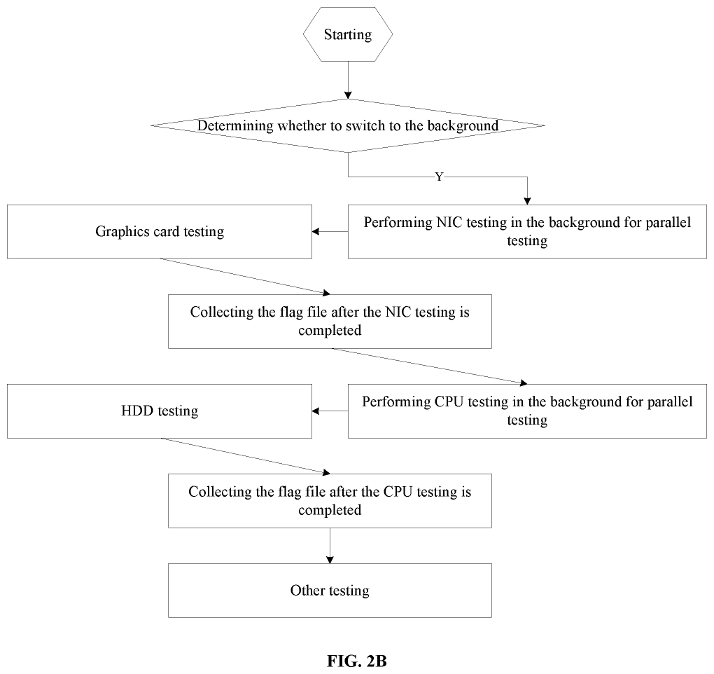

Referring to FIG. 2A and FIG. 2B, which respectively show a schematic flowchart of a test method for process control in an embodiment and a specific embodiment diagram of a test method for process control. As shown in FIG. 2A, the test method for process control specifically includes the following steps:

S21, starting the testing process.

In this embodiment, the starting of the testing process is implemented by python technology.

S22, whether to switch to the second test platform is determined according to the test parameters in the preset test tool after entering the testing process; if yes, executing S23; if not, executing S25, that is, only the first test platform is called to perform serial testing.

In this embodiment, whether to switch to the background for parallel is determined according to whether the test parameters include a parameter marker “background” indicating a need to switch to the second test platform for parallel testing.

As shown in FIG. 2B, according to the test parameter in the preset test tool, that is “background” in “NAME=NIC_TEST PARAMS=background nicstress”, it can be known that the method is required to switch to the background for parallel testing.

S23, switching to the second test platform to call the second test platform for performing parallel testing with the first test platform.

As shown in FIG. 2B, the background is called for the NIC testing, and the foreground is called for the graphics card testing, to achieve parallel testing.

In this embodiment, for preset test tools that need parallel testing, the multi-thread method is used to call and process, and the preset test tools are copied to an independent running directory for operation, so as to avoid conflicts with other preset test tools.

Specifically, the independent running directory may be $ ROOT/TESTINFO/$ TOOLNAME

S24, collecting the flag file that includes the test result after the test is over, so as to detect the parallel testing result. The test result includes passing a parallel testing or failing a parallel testing.

As shown in FIG. 2B, when the preset test tool for the NIC testing is copied to an independent directory for operation, the tool operation result END is directly returned to collect the flag file.

S26, executing S22-S24 cyclically until all preset test tools are tested.

Further referring to FIG. 2B, according to the “background” in the test parameter “INDEX=5 NAME=CPU_TEST PARAMS=background cpu.json” in the preset test tool, it is required to switch to the background for parallel testing.

That is, the background is called for the CPU testing, and the foreground is for the HDD testing to achieve parallel testing.

When the preset test tool for the CPU testing is copied to an independent directory for operation, the tool operation result END is directly returned to collect the flag file.

As shown in the test example shown in FIG. 2B, the overall test takes 190 seconds, which saves the pressure test time by two tools, which is (60−5)*2=110 seconds, compared with 300 seconds of the serial test.

In this embodiment, the formula for the saved time in parallel testing is as follows:

Time saved (seconds)=total test time−(total test time-collecting tool running time in background)/concurrent rounds.

The total test time refers to the total time consumed by all preset test tools running in series. Taking 6 pressure tools, each of which takes 4 hours as an example, it normally takes 24 hours to complete the script pressure test, that is, 86400 seconds.

If the test method for process control described in this embodiment is adopted, the optimal testing process can save 56604 seconds (for detail, 86400−(86400−10)/3=56604), which is equivalent to 24 hours of serial testing. After optimization, it only takes 8 hours to complete the pressure test, saving 16 hours.

The present embodiment further provides a readable storage medium (also called computer readable storage medium) containing a computer program. When executed by a processor, the readable storage medium causes the processor to perform the above-mentioned test method for process control.

Those of ordinary skill will understand computer readable storage medium: all or part of the steps to implement the various method embodiments described above may be accomplished by hardware associated with a computer program. The aforementioned computer program may be stored in a computer readable storage medium. The program, when executed, performs the steps including the above method embodiments. The aforementioned storage medium includes various mediums that may store program codes, such as a ROM, a RAM, a magnetic disk, or an optical disk.

The test method for process control described in this embodiment has the following beneficial effects:

First, the overall test is more flexible and convenient. There is no limitation from the test tools, therefore, the test tools may be flexibly combined.

Second, the grabs of running directories and flag files are relatively independent and would not interfere with each other.

Third, through the conditions of the background parameter marker in the test tool, the testing process coordinates with the test tool to flexibly control the parallelism of the test tool, which greatly saves the pressure measurement test time of the test tool and improves the productivity. The problems of the device to be tested could be discovered early, so that corrections could be made timely to facilitate subsequent testing and shipment.

### Embodiment 2

This embodiment provides a test system for process control, which is adapted to an electronic device configured with a first test platform for serial testing and a second test platform for parallel testing. The test system for process control includes:

a determining module to determine whether to switch to the second test platform according to the test parameters in the preset test tool after entering the testing process; if yes, switching to the second test platform by a calling module to call the second test platform to perform parallel testing with the first test platform; collecting the flag file that includes the test result by a collecting module after the test is over; if not, calling the first test platform by the calling module to perform serial testing.

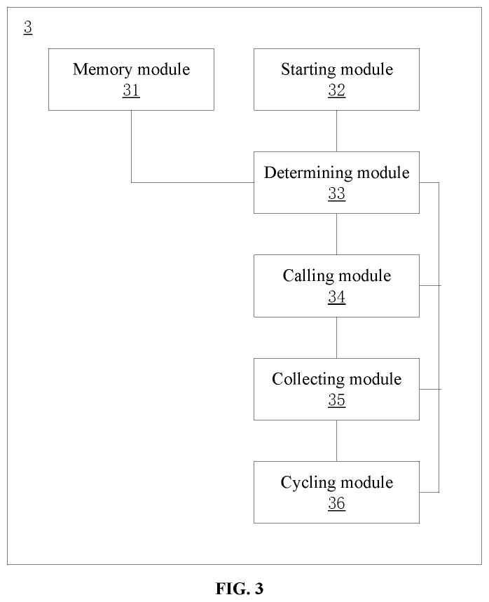

The test system for process control provided in this embodiment will be described in detail below with reference to the drawings. The test system for process control provided in this embodiment will is adapted to an electronic device. Referring to FIG. 3, which is a schematic diagram of a test system for process control in an embodiment. As shown in FIG. 3, the test system 3 for process control includes a memory module 31, a starting module 32, a determining module 33, a calling module 34, a collecting module 35, and a 4 36.

The memory module 31 stores the preset test tool. The preset test tool includes a test script to test a function of the object to test script, the test script may be automatically called by the testing process; the test script includes the test parameters. In this embodiment, when serial testing is required, the test parameters only include functional test parameters of the object to be tested; when parallel testing is required, the test parameters further include a parameter marker to indicate a need to switch to the second test platform for parallel testing. Specifically, the parameter marker that needs to be switched to the background for parallel testing is “background”.

The starting module 32 enables the test system for process control.

In this embodiment, the starting module 32 enables the test system for process control 3 by python technology.

The determining module 33 coupled to the memory module 31 and the starting module 32 determines whether to switch to the second test platform according to the test parameters in the preset test tool after the test system for process control 3 enters the testing process; if yes, switching to the second test platform by a calling module 34; if not, calling the first test platform by the calling module 35 to perform serial testing.

In this embodiment, the determining module 33 determines whether to switch to the background for parallel according to whether the test parameters include a parameter marker “background” indicating a need to switch to the second test platform in parallel.

The second test platform is called to perform parallel testing with the first test platform by switching to the second test platform by the calling module 34.

In this embodiment, for preset test tools (tool) that need parallel testing, the calling module 34 adopts the multi-thread method to call and process, and the preset test tools are copied to an independent running directory for operation, so as to avoid conflicts with other preset test tools.

The collecting module 35 coupled to the calling module 34 collects the flag file that includes the test result after the test is over, so as to detect the parallel testing result. The test result includes passing a parallel testing or failing a parallel testing.

The cycling module 36 that respectively couples to the memory module 31, determining module 33 and calling module 34 cyclically utilizes the memory module 31, determining module 33 and calling module 34 until all preset test tools have been tested.

It should be noted that the division of each module of the above system is only a division of logical functions. In actual implementation, the modules may be integrated into one physical entity in whole or in part, or may be physically separated. And these modules may all be implemented in the form of processing component calling by software, or they may all be implemented in the form of hardware. It is also possible that some modules are implemented in the form of processing component calling by software, and some modules are implemented in the form of hardware. Each module may be a separate processing component, or may be integrated in a chip of the above-mentioned system. In addition, each module may also be stored in the memory of the above system in the form of a program code. The function of the above x module is called and executed by a processing component of the above system. The implementation of other modules is similar. All or part of these modules may be integrated or implemented independently. The processing elements described herein may be an integrated circuit with signal processing capabilities. In the implementation process, each step of the above method or each of the above modules may be completed by an integrated logic circuit of hardware in the processor component or an instruction in a form of software. The above modules may be one or more integrated circuits configured to implement the above method, such as one or more Application Specific Integrated Circuits (ASICs), one or more Digital Signal Processors (DSPs), or one or more Field Programmable Gate Arrays (FPGAs). When one of the above modules is implemented in the form of calling program codes by a processing component, the processing component may be a general processor, such as a Central Processing Unit (CPU) or other processors that may call program codes. These modules may be integrated and implemented in the form of a system-on-a-chip (SOC).

### Embodiment 3

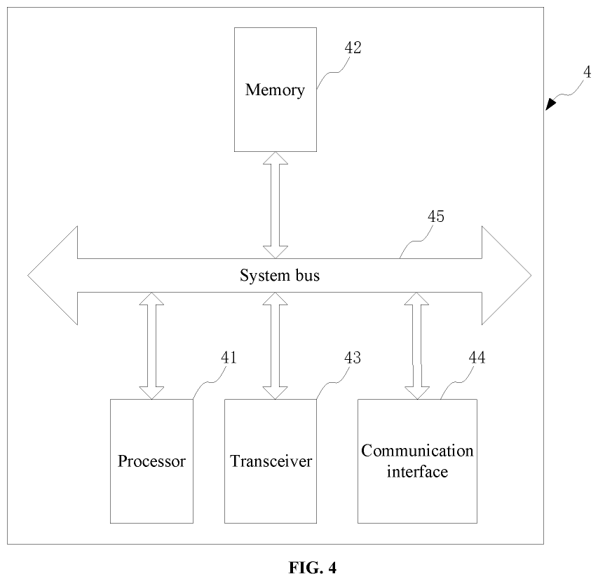

This embodiment provides an electronic device. Referring to FIG. 4, which is a schematic diagram of the hardware of the electronic device. As shown in FIG. 4, the electronic device 4 includes a processor 41, a memory 42, a transceiver 43, a communication interface 44 or/and a system bus 45. The memory 42 and the communication interface 44 are connected and communicate with the processor 41 and the transceiver 43 through the system bus 45. The memory 42 is used to store computer programs. The communication interface 44 is used to communicate with other devices. The processor 41 and the transceiver 43 are used to execute computer programs, so that the electronic device 4 performs the test method for process control as described in embodiment 1.

The system bus mentioned above may be a Peripheral Component Interconnect (PCI) bus or an Extended Industry Standard Architecture (EISA) bus, etc. The system bus can be divided into an address bus, data bus, control bus and so on. For convenience of representation, only a thick line is used in the figure, but it does not mean that there is only one bus or one type of bus. The communication interface is used to implement communication between the database access system and other devices (such as a client, a read-write library, and a read-only library). The memory may include Random Access Memory (RAM), or may also include non-volatile memory, such as at least one disk memory.

The above processor may be a general processor, including a Central Processing Unit (CPU), a Network Processor (NP), etc; it may also be a Digital Signal Processing (DSP), Application Specific Integrated Circuit (ASIC), Field Programmable Gate Array (FPGA) or other programmable logic devices, discrete gate or transistor logic devices, discrete hardware components.

The protection scope of the test method for process control as described in the present disclosure is not limited to the sequence of steps listed in this embodiment. Any scheme realized by adding or subtracting steps or replacing steps of the traditional techniques according to the principle of the present disclosure is included in the protection scope of the present disclosure.

The present disclosure further provides a test system for process control. The test system for process control may implement the test method for process control as described in the present disclosure. However, the realizing system of the test method for process control as described in the present disclosure is not limited to the structure of the test system for process control as listed in this embodiment. Any structural deformation and replacement of traditional techniques made according to the principle of the present disclosure are included in the protection scope of the present disclosure.

The test method, system, readable storage medium and electronic device for process control as described in the present disclosure has the following beneficial effects:

First, the overall test is more flexible and convenient. There is no limitation from the test tools, therefore, the test tools may be flexibly combined.

Second, the grabbing of running directories and flag files are relatively independent and would not interfere with each other.

Third, through the conditions of the background parameter marker in the test tool, the testing process coordinates with the test tool to flexibly control the parallelism of the test tool, which greatly saves the pressure measurement test time of the test tool and improves the productivity. The problems of the device to be tested could be discovered early, so that corrections could be made timely to facilitate subsequent testing and shipment. As mentioned above, the present disclosure effectively overcomes various shortcomings in the existing technology and has high industrial utilization value.

The above-mentioned embodiments are just used for exemplarily describing the principle and effects of the present disclosure instead of limiting the present disclosure. Modifications or variations of the above-described embodiments may be made by those skilled in the art without departing from the spirit and scope of the disclosure. Therefore, all equivalent modifications or changes made by those who have common knowledge in the art without departing from the spirit and technical concept disclosed by the present disclosure shall be still covered by the claims of the present disclosure.

What is claimed is:

1. A test method for process control, which is adapted to an electronic device configured with a first test platform for serial testing and a second test platform for parallel testing; the test method for process control comprises:
determining whether to switch to the second test platform according to a test parameter in a preset test tool after entering a testing process; if yes, switching to the second test platform to call the second test platform to perform parallel testing with the first test platform; collecting a flag file that includes a test result after the test is over; if not, calling only the first test platform to perform serial testing.

2. The test method for process control according to claim 1, wherein the preset test tool comprises a test script for testing a function of an object to be tested; the test script comprises the test parameter.

3. The test method for process control according to claim 2, wherein:
when serial testing is required, the test parameter only includes a functional test parameter of the object to be tested;
when parallel testing is required, the test parameter further includes a parameter marker indicating a need to switch to the second test platform for parallel testing.

4. The test method for process control according to claim 3, wherein if it is necessary to switch to the second test platform, the test method for process control further comprises copying the preset test tool to an independent running directory for operation.

5. The test method for process control according to claim 3, wherein the preset test tools are freely combined on the second test platform to realize parallel testing on the second test platform.

6. The test method for process control according to claim 1, wherein the test result includes passing a parallel testing or failing a parallel testing.

7. A test system for process control, which is adapted to an electronic device configured with a first test platform for serial testing and a second test platform for parallel testing; the test system for process control comprises:
a determining module to determine whether to switch to the second test platform according to a test parameter in a preset test tool after entering a testing process; if yes, switching to the second test platform by a calling module, to call the second test platform to perform parallel testing with the first test platform; collecting a flag file that includes a test result by a collecting module after the test is over; if not, the calling module calls the first test platform to perform serial testing.

8. The test system for process control according to claim 7, further comprising a memory module to store the preset test tool.

9. A readable storage medium having stored thereon a computer program, wherein the computer program implements the test method for process control of claim 1 when executed by a processor.

10. An electronic device, comprising a processor and a memory;
the memory stores a computer program, and the processor executes the computer program stored in the memory, such that the electronic device implements the test method for process control of claim 1.
